(19) United States
(12) Patent Application Publication
(10) Pub. No.: US 2007/0275560 A1
(43) Pub. Date: Nov. 29, 2007

(54) Method of manufacturing semiconductor device

(76) Inventors: Eiichi Nishimura, Nirasaki-Shi (JP); Yoshihide Kihara, Shizuoka-Shi (JP); Yasushi Inata, Hsin--Chu City (TW); Lyndon Lin, Hsin-Chu City (TW)

Correspondence Address: Smith, Gambrell & Russell, Suite 800, 1850 M Street, N.W., Washington, DC, 20036, US

(21) Appl. No.: 11/708,676

(22) Filed: Feb. 21, 2007

Related U.S. Application Data
(60) Provisional application No. 60/781,761, filed on Mar. 14, 2006.

(30) Foreign Application Priority Data
Feb. 22, 2006 (JP) 2006-45298

(51) Int. Cl. H01L 21/3065; C23F 1/08

(52) U.S. Cl. 438/694; 156/345.26; 156/345.48; 257/E21.218

(57) ABSTRACT

A low dielectric constant film containing a silicon, a carbon, an oxygen, and a hydrogen is formed on a substrate as a semiconductor wafer, and a resist film is formed on the low dielectric constant film. Then, the low dielectric constant film is etched with the use of the resist film as a mask to form an exposed surface of the low dielectric constant film. Next, there is deposited a protective film that covers the exposed surface of the low dielectric constant film formed by etching. Thereafter, by ashing with the use of a plasma containing an oxygen, the protective film and the resist film are removed. During the ashing, desorption of the carbon from an insulation film is restrained by the protective film.

### CROSS REFERENCE TO PRIOR APPLICATIONS

This application claims priority from U.S. Provisional Application No. 60/781,761 filed on Mar. 14, 2006, and Japanese Patent Application No. 2006-45298 filed on Feb. 22, 2006. The entire contents of these applications are incorporated herein by reference.

### BACKGROUND OF THE INVENTION

1. Field of the Invention

The present invention relates to a technique, which is utilized when a semiconductor device is manufactured, for plasma-processing an insulation film of a low dielectric constant film containing a silicon, a carbon, an oxygen, and a hydrogen.

2. Background Art

In accordance with a recent tendency for a higher degree of integration of a semiconductor device, a pattern to be formed in a substrate such as a semiconductor wafer (referred to as “wafer” below) has to be formed finer. In order to cope with this demand, a resist material and an exposure technique have been improved, and opening dimensions of a resist mask have considerably become smaller.

At the same time, the number of layers in a device structure has been increased for the higher integration. Since a parasitic capacity needs to be reduced so as to increase an operation speed, a material for a low dielectric constant film serving as an insulation film such as an interlayer insulation has been developed. An example of such a low dielectric constant film is an SiOCH film which is called, e.g., a silicon oxide film containing carbon.

A copper wiring, for example, is embedded in the SiOCH film. Thus, the SiOCH film is etched by, e.g., a CF₄ gas with the use of a photomask and a hard mask, and is then ashed by a plasma obtained by making an oxygen gas in a plasma state. FIG. 11 schematically shows these processes in which the reference number 100 depicts an SiOCH film, 101 depicts a resist mask, and 102 depicts a hard mask.

When the resist mask 101 is ashed by the plasma of oxygen, there is the following problem. Namely, when exposed surfaces of the SiOCH film 100 (sidewalls and bottom surface of a recess) which are exposed by the etching process is exposed to the plasma of oxygen, a carbon as a component of the SiOCH film 100 reacting with the oxygen as a component of the plasma is desorbed from the film, so that SiOCH becomes SiOH.

Thus, a damage layer including damaged portions 103 of SiOH from which the carbon has been desorbed is formed on a surface part of the exposed surfaces exposed by the etching process. Because of a low content of the carbon, a dielectric constant of the damage layer is low. In accordance with a narrower line width of a wiring pattern and thinner thicknesses of a wiring layer and an insulation film, an impact of the superficial part relative to the overall wafer W becomes larger. Thus, the reduction in dielectric constant of a film, even in a superficial part thereof, may result in a deviation of properties of a semiconductor device from designed values.

Techniques described in JP2000-243749A and JP11-87332A have been known as a solution to this problem. In the technique described in JP2000-243749A, in an insulation film having a silicon—hydrogen bond ((HSiO_{1.5})₂ₙ (n=2 to 8)), an exposed part of the film formed by an etching process is processed by a plasma containing neutral active species of a hydroxyl group, so as to oxidize the exposed part. Thus, there is formed on a surface of the exposed part a modification layer that is resistive to the plasma of O₂ gas which is used in the succeeding ashing process. However, since oxidation of the SiOCH film causes desorption of the carbon, this technique cannot be applied to the SiOCH film.

On the other hand, the technique described in JP11-87332A is a solution based on the assumption that an insulation film having an Si—H bond is oxidized by a plasma obtained by making the O₂ gas in a plasma state used in an ashing process, so that an Si—OH bond is produced to cause a damage. The feature of the invention is to reduce the Si—OH bond by a plasma of an H₂ gas to thereby return the Si—OH bond to the Si—H bond. However, as described above, the element (C) in the SiOCH film is desorbed therefrom by the oxygen which is a component in the plasma. Since this reaction is irreversible, the carbon desorbed from the SiOCH film cannot be returned thereto by the plasma of H₂ gas. Therefore, this technique also cannot be applied to the SiOCH film.

### SUMMARY OF THE INVENTION

The present invention has been made in view of the above circumstances. The object of the present invention is to restrain desorption of the carbon from a low dielectric constant film containing a silicon, a carbon, an oxygen, and a hydrogen, when the low dielectric constant film is subjected to an ashing process after an etching process.

In order to achieve this object, in a first aspect, the present invention provides a method of manufacturing a semiconductor device by processing a substrate having a low dielectric constant film containing a silicon, a carbon, an oxygen and a hydrogen, and a resist film formed on the low dielectric constant film, the method comprising the steps of: etching the low dielectric constant film with the use of the resist film as a mask to form an exposed surface of the low dielectric constant film; depositing a protective film to cover the exposed surface of the low dielectric constant film formed by the etching step; and ashing the protective film and the resist film to remove the same by a plasma of an ashing gas containing an oxygen.

Since the protective film is deposited on the exposed surface of the insulation film formed by the etching process, desorption of the carbon from the insulation film by the succeeding ashing process can be restrained, and thus degrade in film quality of the insulation film can be avoided.

In the step of depositing, it is preferable that a gas of a compound of the carbon and the hydrogen is used as a process gas to form a material of the protective film. It is preferable that the compound is selected from the group consisting of: CH₄, C₂H₂, C₂H₄, and C₂H₆.

It is preferable that the step of depositing includes steps of placing the substrate on a lower electrode, supplying a first radiofrequency to a space between the lower electrode and an upper electrode opposed thereto to make a process gas in a plasma state, and supplying a second radiofrequency whose frequency is lower than that of the first radiofrequency to the lower electrode by a biasing radiofrequency source, and that a value obtained by dividing a power supplied by the biasing radiofrequency source by a surface area of the substrate is not less than 100 W/70685.8 mm² and not more than 1000 W/70685.8 mm².

It is preferable that the step of depositing includes a step of making CH₄ in a plasma state in a process atmosphere with a pressure not more than 6.7 Pa.

It is preferable that the steps of etching, depositing, and ashing are successively performed in one processing vessel.

It is preferable that the step of ashing includes steps of placing the substrate on a lower electrode, supplying a third radiofrequency to a space between the lower electrode and an upper electrode opposed thereto to make an ashing gas in a plasma state, and supplying a fourth radiofrequency whose frequency is lower than the third radiofrequency to the lower electrode by a biasing radiofrequency source, and that a value obtained by dividing a power supplied by the biasing radiofrequency source by a surface area of the substrate is not less than 100 W/70685.8 mm² and not more than 500 W/70685.8 mm².

In a second aspect, the present invention provides a plasma processing apparatus for processing with a plasma a substrate having a low dielectric constant film containing a silicon, a carbon, an oxygen and a hydrogen, and a resist film formed on the low dielectric constant film, the apparatus comprising: a processing vessel; a lower electrode disposed in the processing vessel, the lower electrode being configured to place thereon the substrate; an upper electrode disposed in the processing vessel, the upper electrode being opposed to the lower electrode; a plasma-generating radiofrequency source that supplies a radiofrequency for generating a plasma to a space between the lower electrode and the upper electrode; a biasing radiofrequency source that supplies to the lower electrode a biasing radiofrequency whose frequency is lower than that of the radiofrequency for generating a plasma; an etching-gas supply system that supplies into the processing vessel an etching gas for etching the low dielectric constant film with the use of the resist film as a mask to form an exposed surface of the low dielectric constant film; a process-gas supply system that supplies into the processing vessel a process gas to form a material of a protective film that covers the exposed surface of the low dielectric constant film formed by the etching; and an ashing-gas supply system that supplies into the processing vessel an ashing gas containing an oxygen for removing the protective film and the resist film by ashing the same.

In addition, the present invention relates to a storage medium storing a computer program for controlling a plasma processing apparatus to execute the above-described method of manufacturing a semiconductor device.

### BRIEF DESCRIPTION OF THE DRAWINGS

FIG. 1 is a longitudinal sectional view schematically showing an example of a plasma processing apparatus to which the present invention is applied;

FIG. 2 shows sequential steps of a method of manufacturing a semiconductor device according to the present invention;

FIG. 3 is a sectional view of an object to be processed used in an experiment for confirming an effect of the present invention;

FIG. 4 shows sectional views of objects to be processed used in Experiment 1 and Experiment 4 indicating measured positions in the objects;

FIG. 5 is a graph showing a result of Experiment 1;

FIG. 6 shows a graph A showing a result of Example 1 in Experiment 2, a graph B showing a result of Comparative Example 1-1 in Experiment 2, and a sectional view C showing an object to be processed indicating measured positions in the object measured in Experiment 2;

FIG. 7 is a graph showing a result of Experiment 3;

FIG. 8 is a table showing an experimental result of values measured in a representative experiment;

FIG. 9 is a table showing an experimental result of values measured in Experiment 3;

FIG. 10 is a table showing an experimental result of values measured in Experiment 4; and

FIG. 11 shows sectional views of an object to be processed showing a conventional manufacturing process of a semiconductor device.

### DETAILED DESCRIPTION OF THE INVENTION

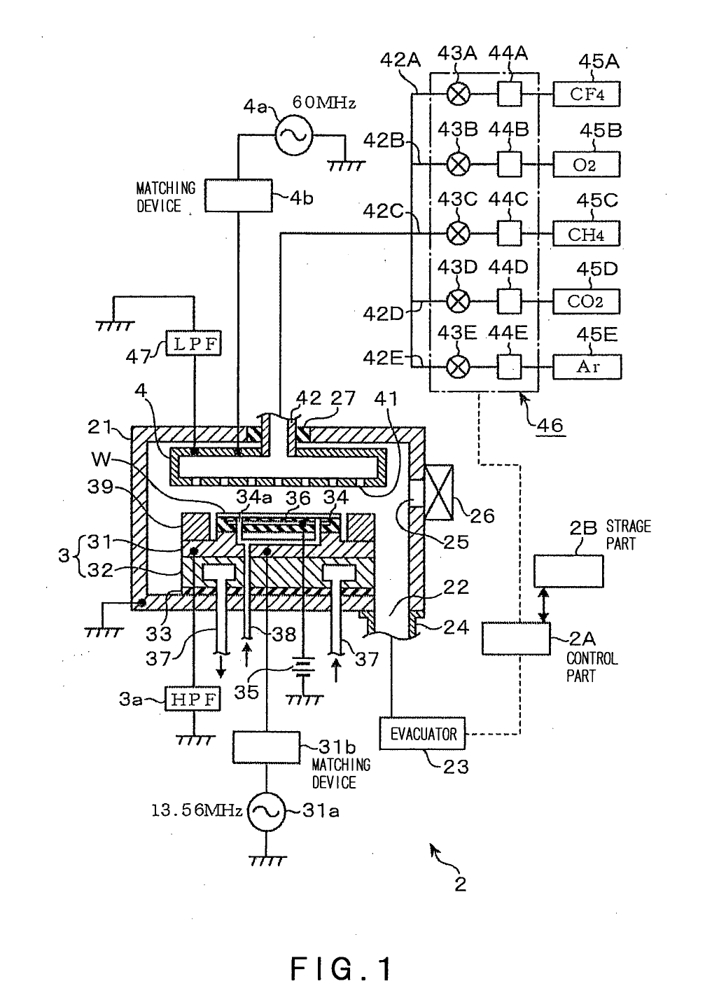

An example of a plasma processing apparatus to which the present invention is applied will be described at first with reference to FIG. 1.

The plasma processing apparatus shown in FIG. 1 comprises a processing vessel 21 defining a vacuum chamber; a stage 3 disposed in the processing vessel 21 on a center part of a bottom surface of the processing vessel 21; and an upper electrode 4 disposed above the stage 3 to be opposed thereto.

The processing vessel 21 is electrically grounded. An evacuator 23 for evacuating an atmosphere in the processing vessel 21 is connected via an evacuation pipe 24 to an outlet port 22 formed in the bottom surface of the processing vessel 21. The evacuator 23 is configured to control an evacuation rate based on a signal from a control part 2A, which is described below, so as to maintain a pressure of the atmosphere in the processing vessel 21 at a desired vacuum degree. A transfer port 25 for a wafer W is formed in a wall surface of the processing vessel 21. The transfer port 25 can be opened/closed by a gate valve 26.

The stage 3 is composed of a lower electrode 31 and a support member 32 that supports the lower electrode 31 from below. The stage 3 is disposed on the bottom surface of the processing vessel 21 through an insulation member 33. An electrostatic chuck 34 is disposed on an upper part of the stage 3. The wafer W is placed on the stage 3 through the electrostatic chuck 34. The electrostatic chuck 34 is made of an insulation material, and accommodates an electrode foil 36 connected to a high-voltage direct current power source 35. When a voltage is applied to the electrode foil 36 from the high-voltage direct current power source 35, a static electricity is generated on a surface of the electrostatic chuck 34, whereby the wafer W placed on the stage 3 is electrostatically attracted and held by the electrostatic chuck 34. The electrostatic chuck 34 is provided with a through-hole 34a through which a backside gas, which is described below, is discharged over the upper part of the electrostatic chuck 34.

The stage 3 includes a cooling medium channel 37 through which a predetermined cooling medium (conventionally known fluorine-group fluid, water, and so on) passes. The cooling medium flowing through the cooling medium channel 37 cools the stage 3 which in turn cools the wafer W placed thereon at a desired temperature. The lower electrode 31 has a temperature sensor, not shown, which continuously monitors a temperature of the wafer W on the lower electrode 31.

A gas channel 38 is formed in the stage 3, through which a heat-conductive gas such as an He (helium) gas is supplied as a backside gas. The gas channel 38 is provided with a plurality of openings opened in the upper surface of the stage 3. Since these openings are in communication with the through-hole 34a formed in the electrostatic chuck 34, when a backside gas is supplied into the gas channel 38, the backside gas flows outward through the through-hole 34a over the upper part of the electrostatic chuck 34. Uniform diffusion of the backside gas in an entire a gap between the electrostatic chuck 34 and the wafer W placed on the electrostatic chuck 34 elevates a thermal conductivity in the gap.

The lower electrode 31 is grounded through a high-pass filter (HPF) 3a. A radiofrequency source 31a that supplies a radiofrequency of, e.g., 13.56 MHz corresponding to a second and a fourth radiofrequencies is connected to the lower electrode 31 through a matching device 31b. In this example, a radiofrequency of 13.56 MHz is supplied as the second and the fourth radiofrequencies. However, two different radiofrequencies, which are selected from a range between, e.g., 2 MHz and 13.56 MHz, may be supplied as the second and the fourth frequencies.

A focus ring 39 is disposed along an outer periphery of the lower electrode 31 to surround the electrostatic chuck 34. Thus, when a plasma is generated, the plasma is focused on the wafer W on the stage 3 through the focus ring 39.

The upper electrode 4 is of a hollow structure to form a gas showerhead with its lower surface having a number of uniformly distributed holes 41 for supplying a process gas into the processing vessel 21 in a dispersive manner. A gas introducing pipe 42 is disposed on a center part of an upper surface of the upper electrode 4. The gas introducing pipe extends to pass through a center part of the upper surface of the processing vessel 21 via the insulation member 27. An upstream side of the gas introducing pipe 42 is diverged into five branch pipes 42A to 42E which are respectively connected to gas supply sources 45A to 45E via valves 43A to 43E and flowrate control parts 44A to 44E. The valves 43A to 43E and the flowrate control parts 44A to 44E constitute a gas supply system 46 that is capable of controlling a gas flowrate and a supply or non-supply operation of each of the gas supply sources 45A to 45E based on a control signal issued from the control part 2A which is described below.

The upper electrode 4 is grounded through a low-pass filter (LPF) 47. A radiofrequency source 4a is connected to the upper electrode 4 through a matching device 4b. The radiofrequency source 4a supplies as a first and a third radiofrequencies a radiofrequency of, e.g., 60 MHz, which is higher than the radiofrequency supplied by the radiofrequency source 31a as the second and the fourth radiofrequencies. In this example, a radiofrequency of 60 MHz is supplied as the first and the third radiofrequencies. However, two different radiofrequencies, which are selected from a range between, e.g., 50 MHz and 150 MHz, may be supplied as the first and the third frequencies.

The radiofrequency supplied from the radiofrequency source 4a connected to the upper electrode 4 corresponds to the first and the third radiofrequencies that make a process gas in a plasma state. The radiofrequency supplied from the radiofrequency source 31a connected to the lower electrode 31 corresponds to the second and the fourth radiofrequencies that apply a biasing power to the wafer W so as to draw ions of a plasma into a surface of the wafer W. The radiofrequency powers 4a and 31a are connected to the control part 2A, and powers to be supplied to the upper electrode 4 and the lower electrode 31 are controlled based on a control signal.

The plasma processing apparatus 2 includes the control part 2A of, e.g., a computer. The control part 2A has a data processing part formed of a program, a memory, and a CPU. Commands are incorporated in the program such that the control part 2A sends control signals to the respective parts of the plasma processing apparatus 2 to sequentially conduct the following steps to thereby plasma-process the wafer W. The memory has a region in which values of various processing parameters such as a process pressure, a process period, a gas flowrate, and an electric power value are written. When the CPU executes the respective commands in the program, these processing parameters are read out, and control signals corresponding to the parameter values are sent to the respective parts of the plasma processing apparatus 2. The program (including a program regarding an input operation and display of the processing parameters) is stored in a storage part 2B of a computer storage medium such as a flexible disc, a compact disc, and an MO (magnet-optical disc), and is installed in the control part 2A.

Next, a method of manufacturing a semiconductor device according to the present invention using the plasma processing apparatus 2 will be described.

At first, the gate valve 26 is opened, and a 300 mm (12 inch) wafer W is loaded into the processing vessel 21 by a transfer mechanism, not shown. The wafer W is horizontally placed on the stage 3, and then the wafer W is electrostatically attracted and held by the stage 3. Thereafter, the transfer mechanism is withdrawn from the processing vessel 21, and the gate valve 26 is closed. Subsequently, a backside gas is supplied from the gas channel 38, and the wafer W is cooled at a predetermined temperature.

Following thereto, the following steps are performed.

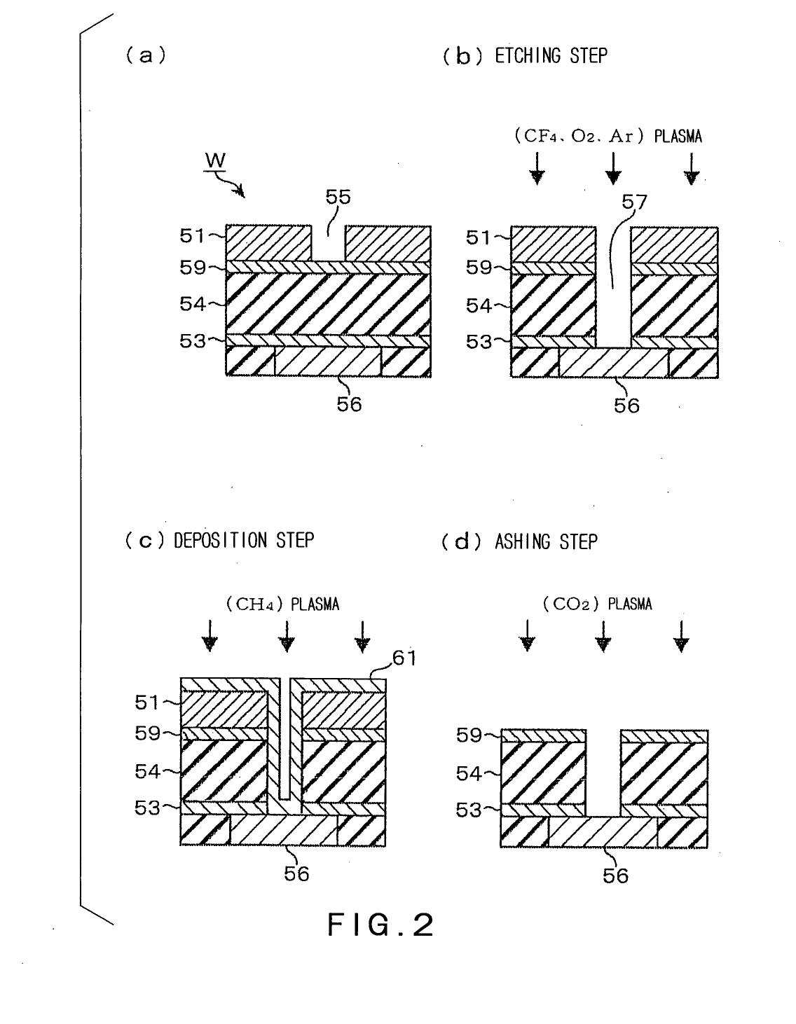

Before describing the steps, a structure of a surface part of the wafer W is described with reference to FIG. 2(a). This example shows a part of a step in which a copper wiring is formed by a dual damascene method. In FIG. 2(a), the reference number 56 depicts a Cu wiring, 53 depicts an SiC film as an etching stopper, 54 depicts an SiOCH film as an interlayer insulation film, 59 depicts an SiO₂ film as a hardmask, 51 depicts a resist film, and 55 depicts an opening.

<Etching Step>

An inside of the processing vessel 21 is evacuated by the evacuator 23 through the evacuation pipe 24, and the inside of the processing vessel 21 is maintained at a predetermined vacuum degree. Then, a CF₄ gas, an O₂ gas, and an Ar gas, for example, are supplied from the gas supply system 46. Thereafter, the first radiofrequency of 60 MHz is supplied to the upper electrode 4 with a power thereof equaling the quotient of, for example, a power (1000 W) divided by a surface area of a substrate (70685.8 mm², when a 300 mm wafer W is used), so that a process gas as a mixture of the above gases is made in a plasma state. Simultaneously, the second radiofrequency of 13.56 MHz is supplied to the lower electrode 31 with a power thereof equaling the quotient of, for example, 300 W divided by 70685.8 mm².

Since active species of a compound of the carbon and the fluorine are contained in the plasma (the process gas in the plasma state), when the SiO₂ film 59 and the SiOCH film 54 are exposed to these active species, a compound is generated by a reaction between atoms in the films and the active species. Thus, as shown in FIG. 2(b), the SiO₂ film 59 and the SiOCH film 54 are etched so that recess 57 is formed.

<Deposition Step>

After completion of the etching process, the power supply from the radiofrequency power sources 4a and 31a is stopped to stop the generation of the plasma in the processing vessel 21, and then the supply of the gases from the gas supply system 46 is stopped. Thereafter, the inside of the processing vessel 21 is evacuated by the evacuator 23 to eliminate the remaining gases, and the inside of the processing vessel 21 is maintained at a predetermined vacuum degree.

A gas of a compound of, e.g., the carbon and the hydrogen, such as a CH₄ gas is supplied from the gas supply system 46, and the inside of the processing vessel 21 is maintained at a pressure not more than 6.7 Pa (50 mTorr). Then, the first radiofrequency of 60 MHz is supplied to the upper electrode 4 with a power thereof equaling the quotient of, for example, 750 W divided by 70685.8 mm², so that a process gas which is a mixture of the above gases is made in a plasma state. Simultaneously, the second radiofrequency of 13.56 MHz as a biasing radiofrequency is supplied to the lower electrode 31 with a power thereof equaling the quotient of, for example, 500 W divided by 70685.8 mm².

As shown in FIG. 2(c), due to the thus generated plasma (the process gas in the plasma state), a protective film 61 made of the carbon or the carbon and the hydrogen is deposited on a surface of the resist mask 51, a wall surface of the opening 55, and a wall surface and a bottom surface of the recess 57. A function of the protective film 61 is to cover and protect an exposed surface of the SiOCH film 54 formed in the etching step, so as to restrain desorption of the carbon therefrom, which may be caused by a plasma used in the following ashing step.

In a case where no radiofrequency is supplied to the lower electrode 31 in the deposition process, the plasma is not intensely drawn into the wafer W, and thus an amount of the protective film 61 deposited on a surface side of the wafer W is increased. Namely, the amount of the protective film 61 deposited on the surface of the resist mask 51 and the wall surface of the opening 55 is increased, while the amount of the protective film 61 deposited on the wall surface and the bottom surface of the recess 57 is decreased. In this case, since it takes a longer time to deposit the protective film 61 of a desired thickness on the wall surface and the bottom surface of the recess 57, a productivity is degraded. Further, it is expected that a longer time is required for the following ashing step, and that a larger amount of residue of carbon is generated by the ashing process which results in particles. In order to avoid this, as described above, a biasing power in a range between the quotient of 100 W divided by 70685.8 mm² and the quotient of 1000 W divided by 70685.8 mm² is applied to the lower electrode 31. Thus, the plasma made by the radiofrequency supplied to the upper electrode 4 is intensely drawn into the wafer W, whereby the protective film 61 can be uniformly deposited on the surface of the resist mask 51, the wall surface of the opening 55, and the wall surface and the bottom surface of the recess 57. Further, it is possible to preferentially deposit the protective film 61 on the wall surface of the recess 57.

As for a gas for depositing the protective film 61, CH₄ may be used, for example. However, not limited thereto, one or more of, e.g., a C₂H₂ gas, a C₂H₄ gas, a C₂H₆ gas, which are a compound of the carbon and the hydrogen, may be used. In addition, together with the above gases, a rare gas such as Ar or N₂ may be used as a diluent gas. In order to uniformly disperse the plasma to reach the bottom surface of the recess 57, when CH₄ is used as a process gas, a process pressure used in this process for depositing the protective film 61 is preferably not more than 6.7 Pa (50 mTorr), which is understood from the below-described examples. However, a range of the process pressure is considered to be optimized depending on the kind of gas to be used.

<Ashing Step>

After the deposition of the protective film 61, the power supply from the radiofrequency power sources 4a and 31a is stopped to stop the generation of the plasma in the processing vessel 21, and then the supply of the gas from the gas supply system 46 is stopped. Thereafter, the inside of the processing vessel 21 is evacuated by the evacuator 23 to eliminate the remaining gases, and the inside of the processing vessel 21 is maintained at a predetermined vacuum degree.

For example, a CO₂ gas is supplied from the gas supply system 46, and the third radiofrequency of 60 MHz is supplied to the upper electrode 4 with a power thereof equaling the quotient of, for example, 200 W divided by 70685.8 mm², so that the gas is made in a plasma state. Simultaneously, the fourth radiofrequency of 13.56 MHz is supplied to the lower electrode 31 with a power thereof equaling the quotient of, for example, 400 W divided by 70685.8 mm².

As shown in FIG. 2(d), due to the thus generated plasma (the gas in the plasma state), the resist mask 51 is removed by ashing the same. Since the protective film 61 is an organic film, the protective film 61 is also removed by ashing the same.

In the ashing step, it is preferable to supply the fourth frequency with a power thereof ranging between, for example, the quotient of 100 W divided by 70685.8 mm², and the quotient of 500 W divided by 70685.8 mm². Within this range, the plasma obtained by making the gas in a plasma state by the third radiofrequency supplied to the upper electrode 4 is intensely drawn into the wafer W, whereby the resist mask 51 can be selectively ashed.

Not limited to the CO₂ gas, an O₂ gas, for example, may be used as a gas for becoming plasma state. However, as compared with the O₂ gas, the use of the CO₂ gas is advantageous in that the CO₂ gas is stable and a generation amount of active species reacting with the carbon in the SiOCH film 54 is significantly smaller, and thus desorption of the carbon from the SiOCH film 54 can be more efficiently restrained. In addition, together with the above gases, a rare gas such as Ar or N₂ may be used as a diluent gas.

In this embodiment, the frequency of the third radiofrequency and the fourth radiofrequency respectively supplied to the upper electrode 4 and the lower electrode 31 are identical to the frequencies of the first radiofrequency and the second radiofrequency, respectively. However, not limited thereto, as long as the frequency of the fourth radiofrequency is lower than the frequency of the third radiofrequency, the third radiofrequency of 50 MHz and the fourth radiofrequency of 2 MHz may be supplied, for example.

After that, an organic film serving as a sacrificial film is buried in the recess 57, and then Cu is buried in the recess 57 by using the organic film so as to form a wiring structure.

In the above embodiment, after the SiOCH film 54 is etched, the protective film 61 is deposited before the ashing process. Thus, during the ashing process, since the exposed surface of the SiOCH film 54 is protected by a reaction caused by the active species of oxygen, desorption of the carbon from the SiOCH film 54 can be suppressed, whereby lowering of a dielectric constant of the SiOCH film 54 can be restrained. As a result, there can be provided a semiconductor device having prescribed electric properties.

As apparent from the following experiments, when the CH₄ gas is used, a process pressure not more than 6.7 Pa (50 mTorr) is advantageous. With this process pressure, the plasma can be uniformly dispersed to reach the bottom surface of the recess 57, and the protective film 61 can be promptly deposited on the exposed surface of the SiOCH film 54. Thus, the deposition amount of the protective film 61 on the surface of the resist mask 51 can be decreased, which results in a reduction in time period required for the ashing step. An optimum value of the condition of the process pressure can be obtained by an experiment for each gas to be used.

In the plasma processing apparatus 2 of the present invention, the etching step for the SiOCH film 54, the deposition step, and the ashing step can be performed in the same processing vessel 21, without unloading the wafer W from the processing vessel 21 and again loading the wafer W thereinto, by suitably changing process conditions such as a gas to be used and a process pressure. Therefore, a time required for the loading/unloading operation of the wafer W can be reduced, and an installation space for the plurality of processing vessels 21 can be saved.

The wafer W to be plasma-processed in the present invention may have a structure in which the resist mask 51 is directly formed on an insulation film such as the SiOCH film 54, or have a structure in which an antireflection film for preventing a reflection upon exposure may be formed between a hardmask such as the SiO₂ film 59 formed on an insulation film such as the SiOCH film 54 and the resist mask 51.

The plasma processing apparatus 2 used in this invention may be of a so-called lower dual frequency type, which supplies the first and the third radiofrequencies for making a process gas in a plasma state to the lower electrode 31 in place of the upper electrode.

### EXPERIMENTS

Next, experiments conducted for confirming the effects of the present invention will be describe below.

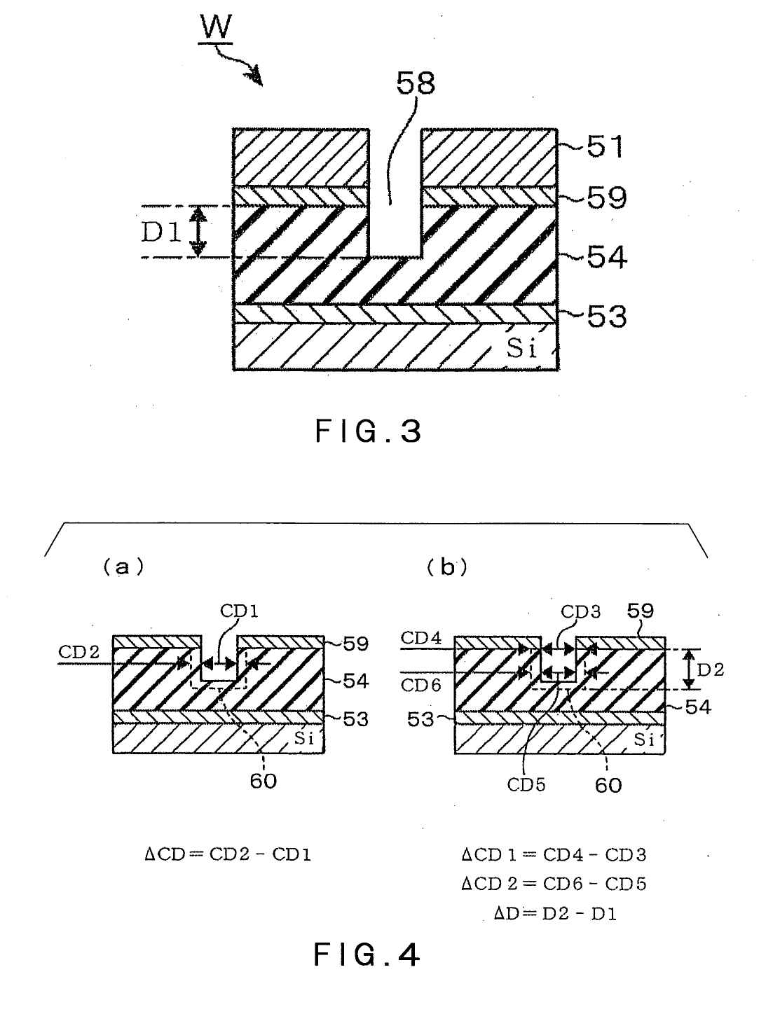

In the following experiments, a test wafer (object to be processed) W as shown in FIG. 3 was used. Namely, on a 300 mm bear silicon wafer, there are stacked an SiC film 53 serving as an etching stopper, an SiOCH film 54 which is a low dielectric constant film, an SiO₂ film 59 used as a hardmask, and a resist mask 51 in which a pattern has been formed, in this order from below. The above-described etching step was conducted on the wafer W under the following process conditions.

| (Etching Step) | | |
|---|---|---|
| Frequency of upper electrode 4 | 60 | MHz |
| Power of upper electrode 4 | 1000 | W |
| Frequency of lower electrode 31 | 13.56 | MHz |
| Power of lower electrode 31 | 300 | W |
| Process pressure | 10 Pa (75 mTorr) | |
| Process gas | CF₄/O₂/Ar = 50/100/100 sccm | |
| Process period | 70 | sec |

When the etching process was performed, a liner groove 58 as a recess 57 was formed in the SiOCH film 54 as shown in FIG. 3. In order to evaluate a damage layer 60 (film-thickness of a layer from which the carbon has been desorbed) on a bottom surface of the groove 58 and a protective film 61, etching conditions were adjusted such that a surface of the SiC film 53 is not etched, i.e., the bottom surface of the groove 58 is positioned near a center part of the SiOCH film 54.

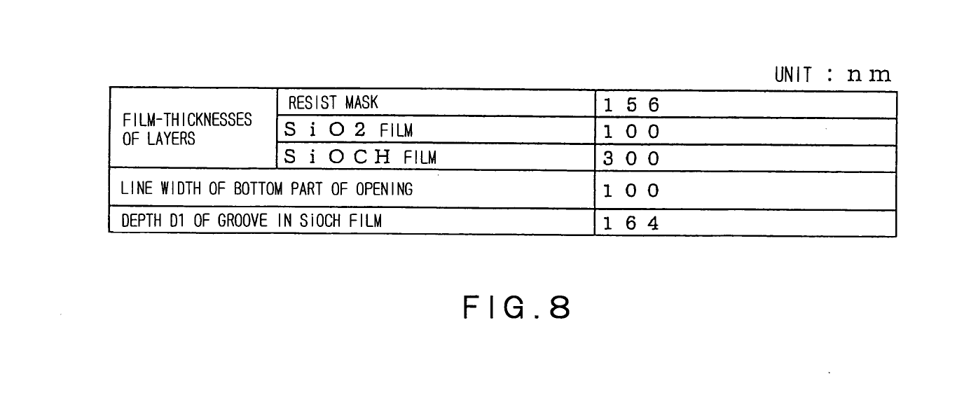

Before the wafer W was used in the experiments, a section of the wafer W was observed by an SEM (scanning-type electron microscope) to obtain film-thicknesses of the respective films, a line width in a bottom part of an opening 55 (interface between the resist mask 51 and the SiO₂ film 59), and a depth D1 of the groove 58 formed in the SiOCH film 54, which are shown in FIG. 8.

As shown in FIG. 3, the depth D1 of the groove 58 formed in the SiOCH film 54 is measured as a depth from the interface between the SiO₂ film 59 and the SiOCH film 54 to the bottom surface of the groove 58. Although the wafer W shown in the data in FIG. 8 is different from the wafers W used in the following experiments, this fact has nearly no effect on an evaluation because the data values in the single wafer W and among the wafers W are highly uniform. In the respective experiments, the plasma processing apparatus 2 shown in FIG. 1 was used as an apparatus for plasma-processing the wafer W.

### Experiment 1

Comparison of generation of the damage layer 60 between a case in which the protective film 61 is deposited before the ashing step, and a case in which the protective film 61 is not deposited before the ashing step.

### A. Example 1

As described above, after the protective film 61 was deposited on the wafer W shown in FIG. 3, the ashing process was performed. The process conditions in the deposition step of the protective film 61 and the ashing step were as follows:

| (Deposition Step) | | |
|---|---|---|
| Frequency of upper electrode 4 | 60 | MHz |
| Power of upper electrode 4 | 750 | W |
| Frequency of lower electrode 31 | 13.56 | MHz |
| Power of lower electrode 31 | 500 | W |
| Process pressure | 1.3 Pa (10 mTorr) | |
| Process gas | CH₄/Ar = 100/100 sccm | |
| Process period | 10 | sec |

| (Ashing Step) | | |
|---|---|---|
| Frequency of upper electrode 4 | 60 | MHz |
| Power of upper electrode 4 | 200 | W |
| Frequency of lower electrode 31 | 13.56 | MHz |
| Power of lower electrode 31 | 400 | W |
| Process pressure | 20 Pa (150 mTorr) | |
| Process gas | CO₂ = 1500 sccm | |
| Process period | 60 | sec |

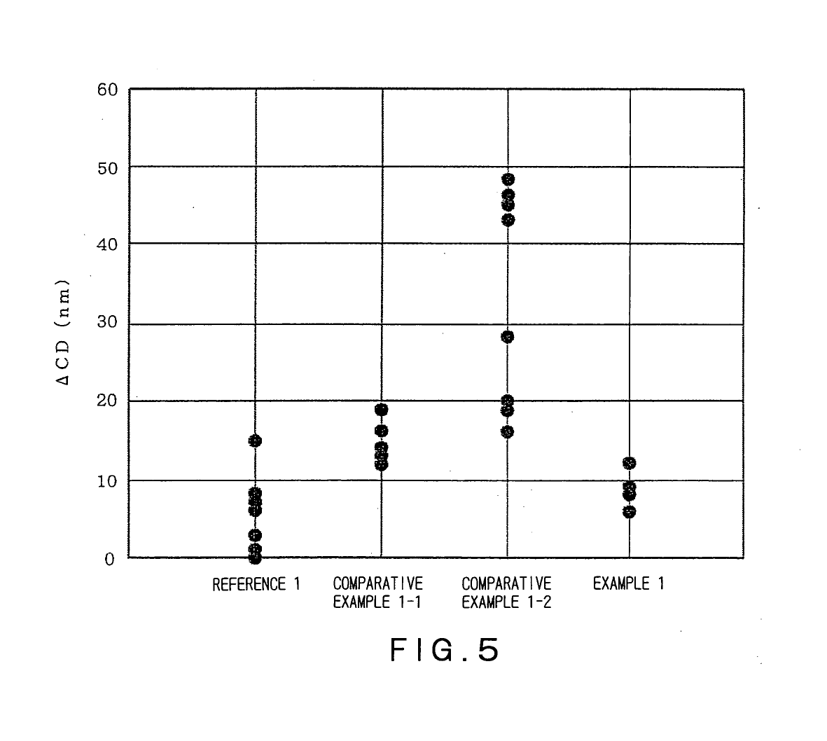

In order to evaluate an amount of the damage layer 60 of the SiOCH film 54, the thus processed wafer W was immersed in a solution containing 1% by weight of HF for 30 seconds, and then a line width CD2 of the groove 58 was measured. As shown in FIG. 4(a), as compared with a line width CD1 of the groove 58 which was not yet immersed in the HF solution, a line width ΔCD (ΔCD=CD2−CD1) of the groove 58, which is equivalent to an increased amount of the line width of the SiOCH film 54 caused by the dissolution by the HF solution, was calculated. That is to say, the damage layer 60 generated by desorption of the carbon from the surface part of the SiOCH film 54 is dissolved in the HF solution, while the SiOCH film 54 from which no carbon is desorbed is not dissolved in the HF solution. Based on this facts, the damage layer 60 on the sidewall of the groove 58 was evaluated by means of the ΔCD. The result is shown in the rightmost side in FIG. 5.

In Experiment 1, the same experiment was repeated for a plurality of times for confirming a reproducibility. The ΔCD of the groove 58 in the center part of the wafer was calculated for each experiment, and the calculated ΔCD values are plotted.

### B. Comparative Example 1-1

The wafer W was subjected to the same processes as those in Example 1, except that the deposition step was not conducted. Namely, the wafer W was ashed and immersed in the HF solution, and the ΔCD was calculated. The result is shown in the second leftmost side in FIG. 5.

### Comparative Example 1-2

The wafer was subjected to the same processes as those in Comparative Example 1, except that the process conditions in the ashing step in Example 1 and Comparative Example 1-1 were changed. Namely, the wafer W was ashed under the following conditions and immersed in the HF solution, and the ΔCD was calculated. The result is shown in the second rightmost side in FIG. 5.

| Power of upper electrode 4 | 1000 | W |
|---|---|---|
| Power of lower electrode 31 | 200 | W |
| Process pressure | 1.3 Pa (10 mTorr) | |
| Process gas | O₂ = 300 sccm | |
| Process period | 27 | sec |

In the ashing step, a case in which CO₂ is used as the process gas (Example 1 and Comparative Example 1-1) and a case in which O₂ is used as the process gas (Comparative Example 1-2) differ from each other in an ashing effect by each plasma (the plasma obtained by the O₂ gas provides a higher ashing effect than the plasma obtained by the CO₂ gas). Thus, the flowrates of the gases and the process periods were adjusted so as to substantially equalize the ashing effects.

### C. Reference 1

Without conducting the ashing step and the deposition step, the etched wafer was immersed in the HF solution, and the ΔCD was calculated. The result is shown in the leftmost side in FIG. 5.

### D. Result and Examination

The results of Example 1 and Comparative Example 1-1 show that, due to the deposition step of the protective film 61, the ΔCD in Example 1 was less than that in Comparative Example 1-1. Thus, it is found that the sidewall of the SiOCH film 54 is protected by the protective film 61 against the plasma of CO₂ gas in the ashing process, and thus desorption of the carbon can be restrained.

The result of Comparative Example 1-2 shows that ΔCD took the largest value when the conventional plasma of O₂ gas was used. Thus, as described above, it is considered that the generation of the damage layer 60 results from the generation of the plasma that is prone to react with the carbon, which invites desorption of the carbon from the SiOCH film 54.

On the other hand, the result of Reference 1 shows that the damage layer 60 was already generated after the etching process of the wafer W. The reason therefor is considered that the carbon liable to be desorbed is preferentially etched in the course of the etching process of the SiOCH film 54. Since the ΔCD takes substantially the same value as that of Example 1, it is found that the damage layer 60 in Example 1 was not generated in the ashing process but in the etching process.

### Experiment 2

### Elemental Analysis

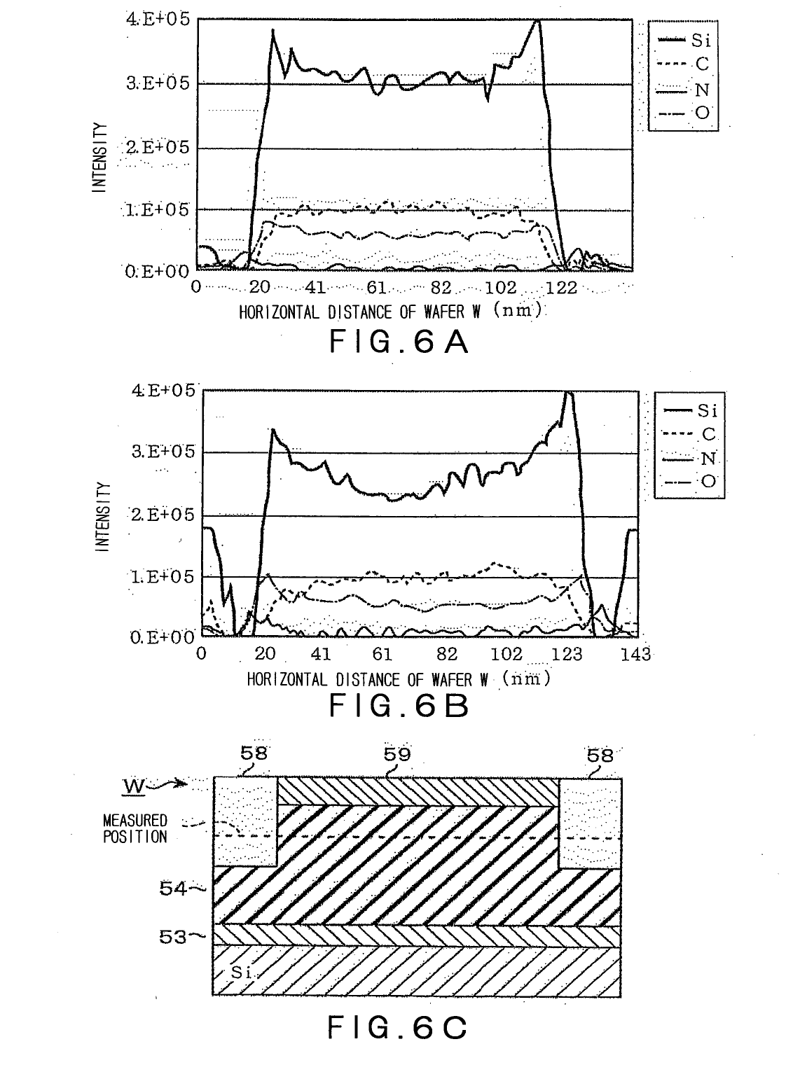

In order to verify whether the evaluation method of the damage layer 60 in Experiment 1 (immersing the wafer W in a solution containing 1% by weight of HF for 30 seconds, and measuring the ΔCD) is an appropriate evaluation method or not, elements of the wafers W processed in Example 1 and Comparative Example 1-1 were analyzed. By using an electron energy loss spectroscopy (EELS), the elemental analysis was conducted by measuring a position corresponding to a position of the measured line width of the groove 58 in Experiment 1. The results are shown in FIG. 6A and FIG. 6B. In order to show an average composition of the SiOCH film 54, as shown in FIG. 6C, FIG. 6A and FIG. 6B represent an arrangement in which the SiOCH film 54 between the grooves 58 is positioned in a center part thereof, and the wall surfaces of the grooves 58 are positioned on the right and left sides.

Both in Example 1 and Comparative Example 1-1, there was confirmed on the sidewall of the groove 58 a layer containing a smaller amount of carbon corresponding to ΔCD confirmed in Experiment 1. FIG. 6A and FIG. 6B show that the damage layer 60 in Example 1 is about 8 nm, and that the damage layer 60 in Comparative Example 1-1 is about 12 nm. Since these values were within a range of the plotted data shown in FIG. 5, it can be confirmed that the evaluation method of the damage layer 60 in Experiment 1 was appropriate.

Similar to Experiment 1, Example 1 and Comparative Example 1-1 were significantly different from each other in a decreased amount of carbon, and Example 1 showed more favorable result than that of the Comparative Example 1-1. Since this analysis shows that an amount of oxygen is increased while an amount of carbon is decreased, it is considered that, in accordance with the decrease in carbon, oxygen is drawn into the SiOCH film 54 for balancing a valence.

### Experiment 3

### Deposition Step

Next, the protective film 61 was deposited on the wafer W shown in FIG. 3 under the following process conditions.

| Frequency of upper electrode 4 | 60 | MHz |
|---|---|---|
| Power of upper electrode 4 | 750 | W |
| Frequency of lower electrode 31 | 13.56 | MHz |
| Power of lower electrode 31 | 500 | W |
| Process pressure | see below | |
| Process gas | CH₄/Ar = 100/100 sccm | |
| Process period | 10 | sec |

The process pressure was set for each example described below.

### Example 3-1

In the above process conditions, the process pressure was set at 1.3 Pa (10 mTorr).

### Example 3-2

In the above process conditions, the process pressure was set at 6.7 Pa (50 mTorr).

### Example 3-3

In the above process conditions, the process pressure was set at 20 Pa (150 mTorr).

### Experiment Result

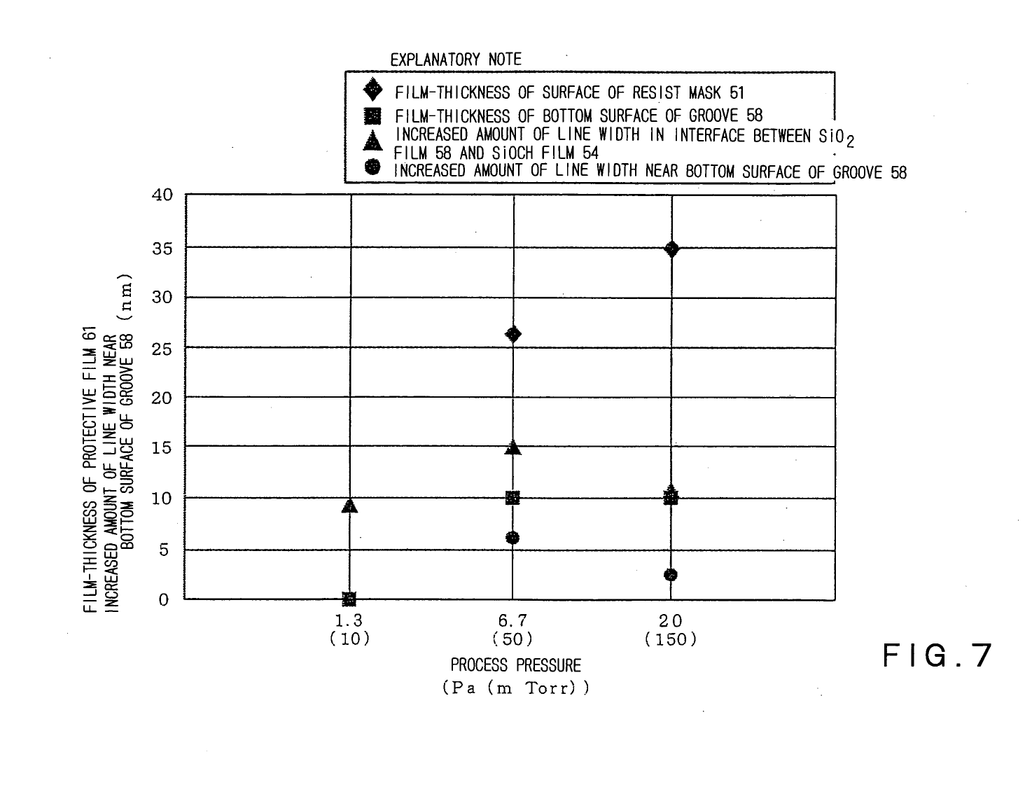

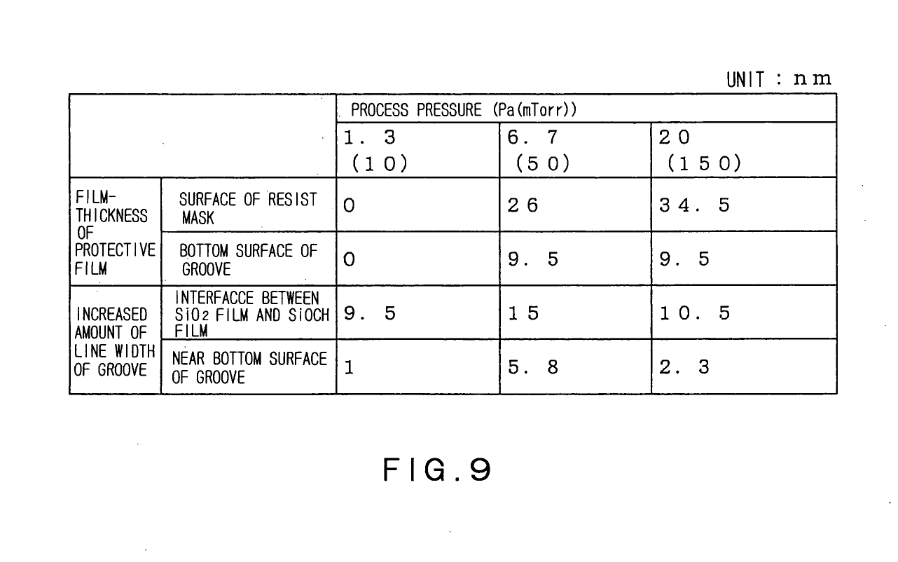

After deposition of the protective film 61, there were measured a film-thickness of the resist mask 51 and a depth of the groove 58, a line width of the groove 58 in an interface between the SiO₂ film 59 and the SiOCH film 54, and a line width of the groove 58 near the bottom surface of the groove 58. Then, from the thicknesses of the respective films and the line width of the groove 58 before the protective film 61 had not been formed thereon, a film-thickness of the protective film 61 deposited on the surface of the resist mask 51, a film-thickness of the protective film 61 deposited on the bottom surface of the groove 58, an increased amount of line width of the groove 58 in the interface between the SiO₂ film 59 and the SiOCH film 54, and an increased amount of line width of the groove 58 near the bottom surface of the grove 58 were calculated. The results are shown in FIGS. 9 and 7.

The higher the process pressure is, the thicker the film-thickness of the protective film 61 on each part tends to be. Thus, it was found that the film-thickness of the protective film 61 can be controlled by the process pressure. The result shown in FIG. 9 will be examined together with the result of the following Example 4.

### Experiment 4

### Ashing Step After Deposition of Protective Film 61

Next, the wafers W on which the protective film 61 had been deposited in Example 3 were ashed under the following process conditions.

| Frequency of upper electrode 4 | 60 | MHz |
|---|---|---|
| Power of upper electrode 4 | 0 | W |
| Frequency of lower electrode 31 | 13.56 | MHz |
| Power of lower electrode 31 | 1100 | W |
| Process pressure | 20 Pa (150 mTorr) | |
| Process gas | CO₂ = 700 sccm | |
| Process period | 21 | sec |

Note that the power 0 W for the upper electrode 4 generally generates no plasma. However, in this example, since a power of 1100 W was applied to the lower electrode 31, a plasma was generated under these conditions.

### Example 4-1

The wafer on which the protective film 61 had been deposited under the process conditions of Example 3-1 was ashed.

### Example 4-2

The wafer on which the protective film 61 had been deposited under the process conditions of Example 3-2 was ashed.

### Example 4-3

The wafer on which the protective film 61 had been deposited under the process conditions of Example 3-3 was ashed.

### Experiment Result

Similar to Experiment 1, the processed wafers W were immersed in a solution containing 1% by weight of HF for 30 seconds. Then, regarding the increased amount ΔCD of the line width of the groove 58 calculated in Experiment 1, a value of the ΔCD in the interface between the SiO₂ film 59 and the SiOCH film 54, and a value of ΔCD near the bottom surface of the groove 58 were measured.

Namely, as shown in FIG. 4(b), in each of the wafers W immersed in the HF solution, a line width CD4 of the groove 58 in the interface between the SiO₂ film 59 and the SiOCH film 54, and a line width CD6 near the bottom surface of the groove 58 were measured. The obtained values CD4 and CD6 were compared to the values CD3 and CD5 which were the values before the protective film 61 had not been deposited in the respective Examples 3, so as to calculate a ΔCD1 (ΔCD1=CD4−CD3) and a ΔCD2 (ΔCD2=CD6−CD5). In addition, a depth D2 of the groove 58 formed in the SiOCH film 54 after immersion in the HF solution was measured, and the obtained value D2 was compared to the value D1 before the protective film 61 had not been formed, so as to calculate a ΔD (ΔD=D2−D1) which is a value corresponding to an increased amount of the depth formed in the groove 58.

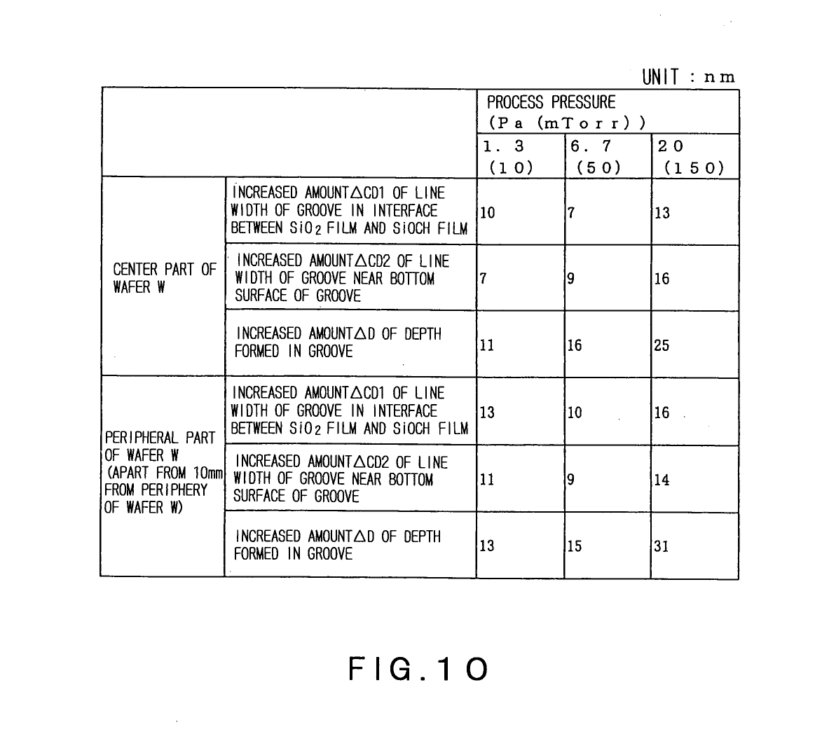

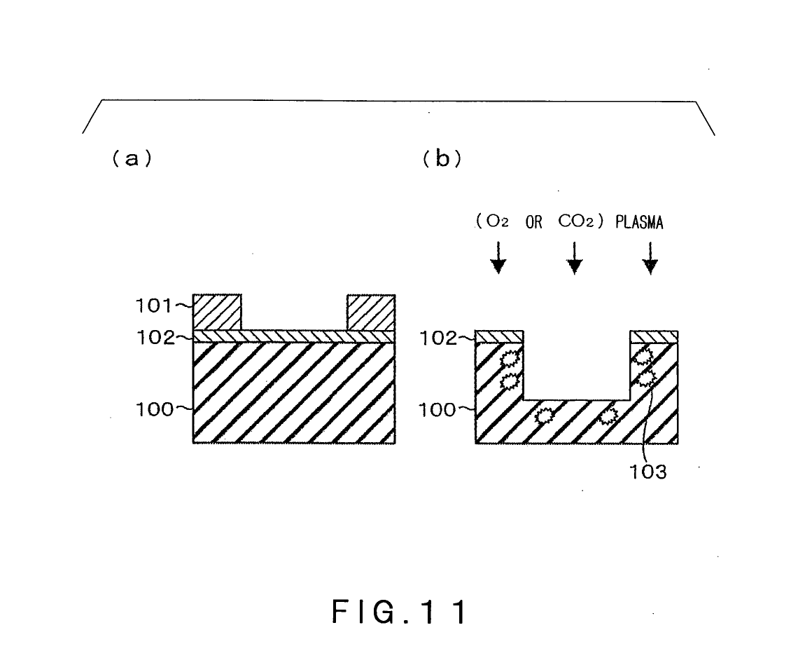

In Experiment 4, in order to confirm a difference between the damage layer 60 in a center part of the wafer W and the damage layer 60 in a peripheral part of the wafer W, values at a center part of the wafer W and a peripheral part of the wafer W (10 mm apart from a periphery of the wafer W) were measured. The result is shown in FIG. 10.

This result shows that, in accordance with the increase in the process pressure in the deposition process in Experiment 3, the respective values ΔCD1, ΔCD2, and ΔD tend to increase.

Referring to FIG. 10 in comparison with FIG. 9, it is shown that, as compared with the process pressure in the deposition step being 20 Pa (150 mTorr), when the process pressure is 1.3 Pa (10 mTorr), the thickness of the protective film 61 is smaller, while the damage layer 60 is thinner (the values ΔCD1, the ΔCD2, and the ΔD are smaller). The reason for this phenomenon is supposed that, when the process pressure is 1.3 Pa (10 mTorr), the C—C bond in the protective film 61 is stronger, or an amount of C—C bond in the protective film 61 is larger, and thus the protective film 61 is highly resistive against an attack of the active species of the oxygen. On the other hand, as compared with the process pressure in the deposition step being 20 Pa (150 mTorr), when the process pressure is 6.7 Pa (50 mTorr), the film-thickness of the protective film 61 is larger. It is considered that the thickness of the damage layer 60 in the former case is smaller than that of the latter case, corresponding to the film-thickness of the protective film 61.

As seen above, it is estimated that a film quality of the protective film 61 in an area where the process pressure is low is favorable in terms of a resistivity against the plasma of oxygen. As a result, it can be said that the process pressure in the deposition step is preferably not more than 6.7 Pa (50 mTorr).

1. A method of manufacturing a semiconductor device by processing a substrate having a low dielectric constant film containing a silicon, a carbon, an oxygen and a hydrogen, and a resist film formed on the low dielectric constant film, the method comprising the steps of:
etching the low dielectric constant film with the use of the resist film as a mask to form an exposed surface of the low dielectric constant film;
depositing a protective film to cover the exposed surface of the low dielectric constant film formed by the etching step; and
ashing the protective film and the resist film to remove the same by a plasma of an ashing gas containing an oxygen.

2. The method of manufacturing a semiconductor device according to claim 1,
wherein, in said step of depositing, a gas of a compound of the carbon and the hydrogen is used as a process gas to form a material of the protective film.

3. The method of manufacturing a semiconductor device according to claim 2,
wherein the compound is selected from the group consisting of: CH₄, C₂H₂, C₂H₄, and C₂H₆.

4. The method of manufacturing a semiconductor device according to claim 1,
wherein said step of depositing includes steps of placing the substrate on a lower electrode, supplying a first radiofrequency to a space between the lower electrode and an upper electrode opposed thereto to make a process gas in a plasma state, and supplying a second radiofrequency whose frequency is lower than that of the first radiofrequency to the lower electrode by a biasing radiofrequency source, and
a value obtained by dividing a power supplied by the biasing radiofrequency source by a surface area of the substrate is not less than 100 W/70685.8 mm² and not more than 1000 W/70685.8 mm².

5. The method of manufacturing a semiconductor device according to claim 1,
wherein said step of depositing includes a step of making CH₄ in a plasma state in a process atmosphere with a pressure not more than 6.7 Pa.

6. The method of manufacturing a semiconductor device according to claim 4,
wherein said step of depositing includes a step of making CH₄ in a plasma state in a process atmosphere with a pressure not more than 6.7 Pa.

7. The method of manufacturing a semiconductor device according to claim 1,
wherein said steps of etching, depositing, and ashing are successively performed in one processing vessel.

8. The method of manufacturing a semiconductor device according to claim 1,
wherein said step of ashing includes steps of placing the substrate on a lower electrode, supplying a third radiofrequency to a space between the lower electrode and an upper electrode opposed thereto to make an ashing gas in a plasma state, and supplying a fourth radiofrequency whose frequency is lower than the third radiofrequency to the lower electrode by a biasing radiofrequency source, and
a value obtained by dividing a power supplied by the biasing radiofrequency source by a surface area of the substrate is not less than 100 W/70685.8 mm² and not more than 500 W/70685.8 mm².

9. The method of manufacturing a semiconductor device according to claim 6,
wherein said step of ashing includes steps of placing the substrate on a lower electrode, supplying a third radiofrequency to a space between the lower electrode and an upper electrode opposed thereto to make an ashing gas in a plasma state, and supplying a fourth radiofrequency whose frequency is lower than the third radiofrequency to the lower electrode by a biasing radiofrequency source, and
a value obtained by dividing a power supplied by the biasing radiofrequency source by a surface area of the substrate is not less than 100 W/70685.8 mm² and not more than 500 W/70685.8 mm².

10. A plasma processing apparatus for processing with a plasma a substrate having a low dielectric constant film containing a silicon, a carbon, an oxygen and a hydrogen, and a resist film formed on the low dielectric constant film, the apparatus comprising:
a processing vessel;
a lower electrode disposed in the processing vessel, the lower electrode being configured to place thereon the substrate;
an upper electrode disposed in the processing vessel, the upper electrode being opposed to the lower electrode;
a plasma-generating radiofrequency source that supplies a radiofrequency for generating a plasma to a space between the lower electrode and the upper electrode;
a biasing radiofrequency source that supplies to the lower electrode a biasing radiofrequency whose frequency is lower than that of the radiofrequency for generating a plasma;
an etching-gas supply system that supplies into the processing vessel an etching gas for etching the low dielectric constant film with the use of the resist film as a mask to form an exposed surface of the low dielectric constant film;
a process-gas supply system that supplies into the processing vessel a process gas to form a material of a protective film that covers the exposed surface of the low dielectric constant film formed by the etching; and
an ashing-gas supply system that supplies into the processing vessel an ashing gas containing an oxygen for removing the protective film and the resist film by ashing the same.

11. The plasma processing apparatus according to claim 10,
wherein the process gas to form a material of the protective film is a compound of the carbon and the hydrogen.

12. The plasma processing apparatus according to claim 11,
wherein the compound is selected from the group consisting of: CH₄, C₂H₂, C₂H₄, and C₂H₆.

13. The plasma processing apparatus according to claim 10 further comprising a control part that controls the biasing radiofrequency source,
wherein, when the process gas is supplied into the processing vessel by the process-gas supply system, the control part controls a power supplied by the biasing radiofrequency source so that a value obtained by dividing the power by a surface area of the substrate is not less than 100 W/70685.8 mm² and not more than 1000 W/70685.8 mm².

14. The plasma processing apparatus according to claim 10, further comprising:
an evacuator that evacuates an atmosphere in the processing vessel; and
a control part that controls the evacuator;
wherein the process gas to form a material of the protective film is a CH₄ gas, and
when the CH₄ gas is supplied into the processing vessel by the process gas supply system, the control part controls an evacuation rate of the evacuator to make a pressure of the atmosphere in the processing vessel be not more than 6.7 Pa.

15. The plasma processing apparatus according to claim 10, further comprising a control part that controls the biasing radiofrequency source,
wherein, when the ashing gas is supplied into the processing vessel by the ashing-gas supply system, the control part controls a power supplied by the biasing radiofrequency source so that a value obtained by dividing the power by a surface area of the substrate is not less than 100 W/70685.8 mm² and not more than 500 W/70685.8 mm².

16. A storage medium storing a computer program for controlling a plasma processing apparatus to execute the method of manufacturing a semiconductor device according to claim 1.
